(19) United States
(12) Patent Application Publication
(10) Pub. No.: US 2009/0080133 A1
(43) Pub. Date: Mar. 26, 2009

(54) ELECTRONIC MODULE FOR AC/DC COIL WITHIN AN ELECTROMAGNETIC CONTACTOR

(75) Inventors: Nilanjan Ray Chaudhuri, Garia Kolkata (IN); Avijit Saha, Behala Kolkata (IN); Nanda Kishore Pamidi, Andhra Pradesh (IN); G. Kalyana Sundaram, Karnataka State (IN); Sirosh Sivasankaran, Karnataka State (IN); Pasupuleti Kalpana, Andhra Pradesh (IN)

Correspondence Address: CANTOR COLBURN, LLP, 20 Church Street, 22nd Floor, Hartford, CT, 06103, US

(73) Assignee: GENERAL ELECTRIC COMPANY, Schenectady, NY (US)

(21) Appl. No.: 11/859,396

(22) Filed: Sep. 21, 2007

(51) Int. Cl. H01F 7/18; G01R 19/00; H01F 7/06

(52) U.S. Cl. 361/152; 324/76.11; 361/153

(57) ABSTRACT

The present invention relates to a device and a method for utilizing a control module as an interfaced control of a dually configured AC/DC control coil comprising monitoring a coil voltage of the control coil, determining if the coil voltage is greater than a predetermined dropout voltage, and determining if the coil voltage is greater than a predetermined pickup voltage. Further, a generated astable pulse is reset in the event that the coil voltage is determined to be less than the predetermined dropout voltage.

### FIELD OF THE INVENTION

This invention relates to electromagnetic contactors and particularly to the implementation of electromagnetic contactors comprising AC/DC coils.

### DESCRIPTION OF BACKGROUND

Contactors are utilized as electrically controlled devices for power circuits. Conventionally, contactors are assembled from three primary elements: a contact structure for carrying current, an electromagnetic assembly for providing the force to close the contacts of the contact structure, and a frame housing for enclosing the contact and electromagnetic assembly. Typically, in the instance that the contacts of a contactor have been place in a closed state, the impedance of a control coil within the electromagnetic assembly limits the current within the control coil when an AC power supply is delivered to the coil.

However, in the event that the power supply is a DC supply, there is no reactance present to limit the current within the control coil. The only resistance that is available to limit the DC supply is that of the control coil itself, therefore necessitating the implementation of DC control coils that are much larger in size than AC control coils for contactors that are specified for use within DC coil supply systems. The disparity in coils sizes leads to increased manufacturing costs since two contactor devices comprising differing control coils must be constructed for devices constructed for similar voltage ratings. Further, the electromagnet designs for AC & DC contactors are also different.

Therefore, there exists a need for a contactor device that can be used in conjunction with AC and DC power supply systems.

### SUMMARY OF THE INVENTION

An exemplary embodiment of the present invention comprises an electromagnetic contactor device. The electromagnetic contactor device comprises a control module. The control module comprises a power circuit, wherein the power circuit comprises a coil assembly, further, the power circuit is configured to receive an AC or DC supply voltage. The control module also comprises an analog control circuit, the analog control circuit being in communication with the power circuit, wherein the control circuit is configured to monitor a coil voltage within the coil assembly.

A further exemplary embodiment of the present invention comprises a method for utilizing a control module as an interfaced control of an AC/DC control coil. The method comprises monitoring a coil voltage of the control coil, determining if the coil voltage is greater than a predetermined dropout voltage, and determining if the coil voltage is greater than a predetermined pickup voltage. The method also comprises resetting an astable pulse in the event that the coil voltage is determined to be less than the predetermined dropout voltage.

Additional features and advantages are realized through the techniques of the present invention. Yet further embodiments and aspects of the invention are described in detail herein and are considered a part of the claimed invention.

### BRIEF DESCRIPTION OF THE DRAWINGS

The subject matter that is regarded as the invention is particularly pointed out and distinctly claimed in the claims at the conclusion of the specification. The foregoing and other objects, features, and advantages of the invention are apparent from the following detailed description taken in conjunction with the accompanying drawings in which:

FIG. 1 is a diagram showing details of a cross-section of a contactor device in accordance with embodiments of the present invention.

FIG. 2 is a diagram of an electronic control module in accordance with embodiments of the present invention.

FIG. 3 is a diagram of an exemplary switching voltage regulator that can be implemented in accordance with exemplary embodiments of the present invention.

FIG. 4 is a flow diagram detailing a method for utilizing a control module as an interfaced control of an AC/DC control coil in accordance with embodiments of the present invention.

The detailed description explains the exemplary embodiments of the invention, together with advantages and features, by way of example with reference to the drawings.

### DETAILED DESCRIPTION OF THE INVENTION

One or more exemplary embodiments of the invention are described below in detail. The disclosed embodiments are intended to be illustrative only since numerous modifications and variations therein will be apparent to those of ordinary skill in the art. In reference to the drawings, like numbers will indicate like parts continuously throughout the views.

Exemplary embodiments of the present invention comprise a magnet coil assembly that forms an important aspect of the control circuit of the present invention. The present invention implements a novel AC/DC coil by the operations that are initiated within an electronic control module that is interfaced with a supply voltage and the control coil. The control module allows for a sufficient monostable time period of switching that allows for the movable contacts of a contactor to pickup or make contact with the non-movable contacts of the contactor. This period is followed by an astable period that assures that a hold-on condition will be sustained within the contactor. The pulse generator utilized within exemplary embodiments of the present invention is configured to output astable and monostable pulses. Generally, astable pulse generation refers to an oscillating pulse that has no permanent state since it continuously changes its state, producing a square wave output of a predetermined timing cycle. In contrast, a monostable pulse generation outputs a single output pulse—HIGH or LOW—when a suitable pulse trigger signal is applied. This trigger signal initiates a timing cycle which, causes the output of the monostable to change state at the start of the timing cycle and remain in this secondary state until it resets itself back to its original state at the end of the timing cycle.

Within aspects of exemplary embodiments of the present invention, the duty-cycle of an astable period is increased in the event of a decreasing coil supply voltage, thus ensuring an optimum contact holding force. Further, as currently presented, the present invention does not require the use of a micro-controller or a driver-circuit to accomplish the operational goals of the present invention. Additionally, all circuits that are implemented within the exemplary embodiments of the present invention are purely analog based.

As mentioned above, the present invention implements an AC/DC coil within exemplary embodiments. Typically, DC supply coils are much larger in scale than their AC equivalents. However, the present invention does not require the separate design of an AC or DC coil within exemplary embodiments. Within the exemplary embodiments of the present invention the AC and DC supply coils are featured within the same coil, thereby substantially reducing the size of DC coils that can be implemented within a contactor device. Thus, same electromagnet system, whether AC or DC based, is suitable to enable the operational functions of the DC contactor of the exemplary embodiments of the present invention. This inventive aspect is accomplished by cutting or lowering the dc supply voltage during a hold-on condition within the contactor, thus eliminating the need to have a larger DC supply coil. A further advantage of the present invention is that by instituting a variable duty cycle in the astable mode of operation, the duty cycle increases as the voltage decreases, thus avoiding nuisance tripping events.

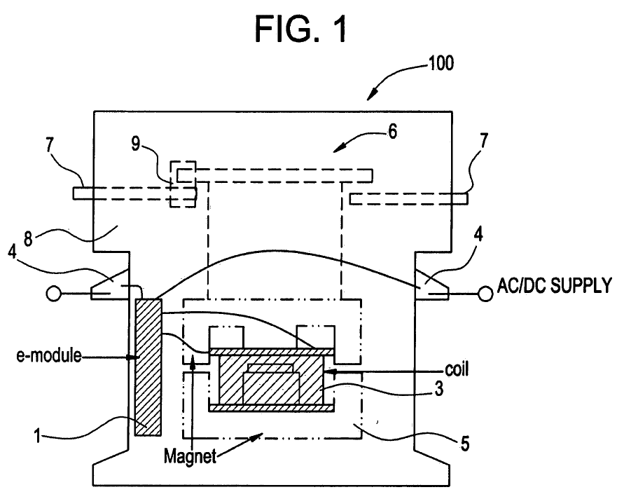

FIG. 1 shows a cross-sectional diagram of a contactor device 100. As shown, the contactor 100 comprises a movable magnetic control coil magnet contact assembly 6, a coil assembly 3, a fixed magnet with base plate assembly 5, and fixed contact plates 7. During a hold-on condition, the fixed 7 and the moving 6 contacts remain in contact at the contact tip 9. The electronic control module 1 is interfaced between the control coil power supply terminals 4 and the control coil assembly 3. The elements of the contactor are enclosed within a housing 8.

In operation the electronic control module 1 is physically configured as a functional intermediary between the contactor 100 and the power supply for the contactor 100. This aspect is essential for allowing the exemplary embodiments of the present invention to provide the use of the same control coil assembly 3 for both AC and DC power supplies. The electronic control module 1 comprises a power supply circuit comprising a buck converter circuit; and a control circuit. Each of the fore-mentioned operational components further comprises a series of functional sub-components. The power supply circuit acts as the constant output voltage source for the various ranges of input voltage—though the output voltage of the power supply circuit remains fixed at 9V.

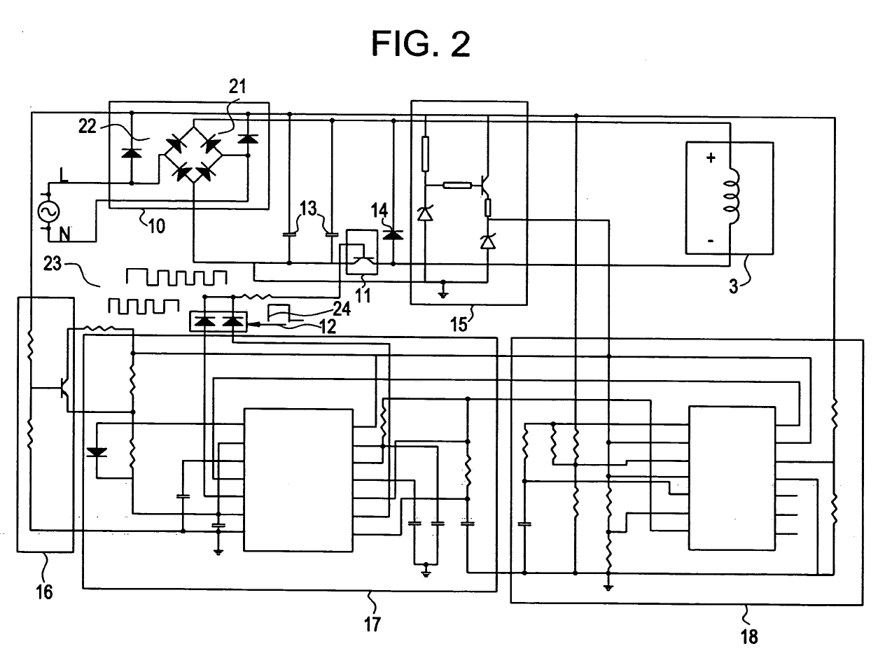

FIG. 2 shows a diagram detailing the elements of the electronic control module 1. As shown, a bridge rectifying circuit 10 is used for rectifying a supply voltage to the coil assembly 3, wherein the supply voltage can be either an AC or DC supply voltage. Two electrolytic capacitors 13 are implemented to separately filter the voltage for the power supply circuit and the control circuit. Within exemplary embodiments of the present invention the power circuit comprises the bridge rectifier 10, the filter 13, the coil assembly 3, a diode 14, and a switching device 11. Further, the control circuit comprises a pulse-generator 17, a control logic circuit 18, an OR circuit 12, a voltage dependent resistor circuit 16, and a buck converter (step down DC to DC converter) control voltage regulator circuit 15.

As shown, the rectifier circuit 10 comprises a bridge rectifier 22 and a pair of diodes 21. The output from the bridge is fed to the power circuit. Further, the pair of diodes 21 feed the control voltage regulator circuit 15. The positive terminal of the bridge rectifier 22 is connected to one of the coil terminals 4; the other coil terminal 4 is connected in series with the switching device 11. Within further exemplary embodiments of the present invention, the use of the rectifier circuit 10 can be dispensed with in the instance that it is desired that a DC power supply be utilized.

The control circuit requires a power supply of 9V, wherein a constant voltage is supplied to the control circuit via the control voltage regulator circuit 15 (e.g., this constant voltage can be supplied using a low drop-out (LDO) voltage regulator in combination with a switching voltage regulator circuit). To enable exemplary embodiments of the present invention to operate over a wide range of voltages the input voltages are divide it into three different ranges: a low range of 12V, a mid-range of 24V-60V; and a high-range of 72V-440V.

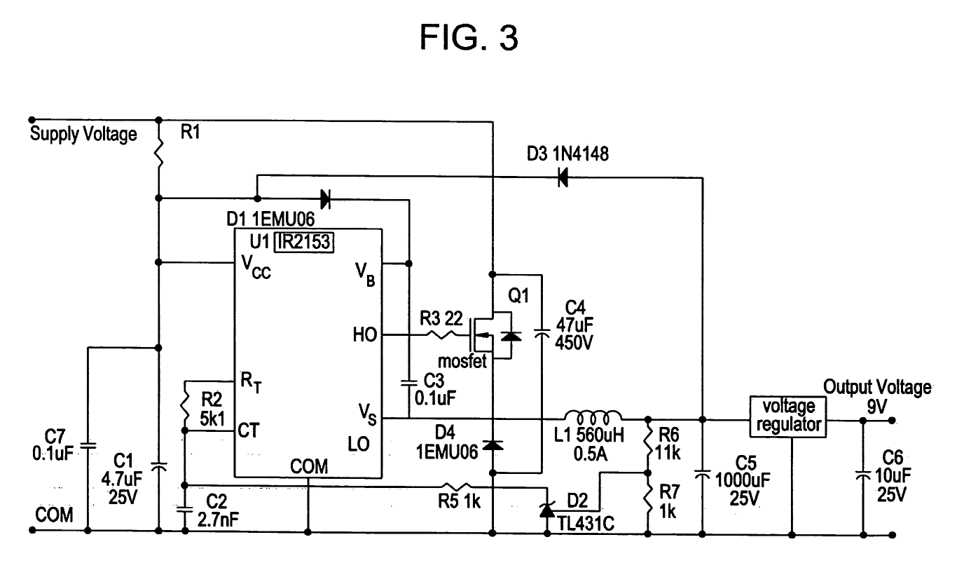

In the instance of the occurrence of a low coil voltage of 12V, a low dropout voltage regulator is implemented. In the instance of the occurrence of a mid-range voltage of 24V-60V, a switching circuit is implemented in combination with the LDO voltage regulator. An exemplary switching circuit that can be implemented within exemplary embodiments of the present invention is shown in FIG. 3. The switching voltage regulator circuit shown in FIG. 3 comprises a switching IC IR2153 that drives the MOSFET Q1 of the buck converter. In order to maintain a constant output voltage, feedback is accomplished with the utilization of a TL431 diode D2. The input resistance R1 plays a very important role in determining the circuit input voltage range. As such, the input resistance R1 is utilized with the LDO voltage regulator. The switching voltage regulator of FIG. 3 is again utilized in the instance of the occurrence of a high-range voltage of 72V-440V. Further, the value of the input resistance R1 is accordingly adjusted in order to obtain a required voltage range.

While it is not possible to determine the input voltage supplied to the coil assembly 3. The pickup voltage level changes depending upon the voltage rating of the coil assembly 3. In order to allow the contactor 6 to pick up at the correct pickup point the potential divider can be configured to be manually configured. Within exemplary embodiments of the present invention this option can be provided to a user via an accessible DIP selection switch, wherein the selection ranges are 12V, 24V, 48V, 60V, 72V, 110V, 230V, and 440V.

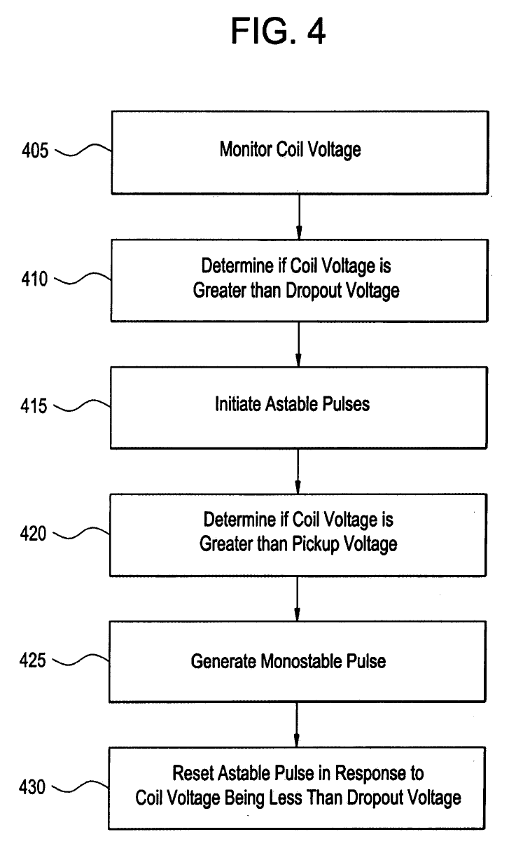

The control logic circuit 18 monitors the coil assembly 3 supply voltage (step 405 of FIG. 4), and in response to its monitoring activities, produces required control outputs. A determination is made at the control logic circuit 18 to ascertain if the supply voltage is greater than a dropout voltage that has been predetermined for the contactor (step 410). When the coil assembly 3 supply voltage is greater than the predetermined dropout voltage of the contactor, the controller 18 sets a RESET input for an astable pulse 23 that is generated at the pulse generator 17 to HIGH. The pulse generator 17 generates the astable pulses 23 with high frequency (e.g., at approximately 500 Hz) (step 415). However, the coil assembly current in this instance is not enough for the contact pickup with the contactor 100. Within aspects of the present invention the pickup voltage of the contactor 100 is always greater than the dropout voltage.

The control logic further determines if the coil voltage is greater than the pickup voltage of the contactor 100 (step 420). In the event that the coil voltage is greater than the pickup voltage of the contactor 100, the controller 18 sets the RESET input of the monostable pulse generator of the pulse generator 17 to HIGH. As the supply voltage crosses the pickup voltage, the pulse generator 17 generates a monostable pulse 24 (step 425). The monostable pulse 24 is output for a time period more than or equal to the predetermined pickup time of the contactor 100. The OR circuit 12 adds together the two outputs of the pulse generator 17 (i.e., the astable output & the monostable output). The resultant output comprises the monostable pulse of the designed time period. The generation of this output allows for a proper pickup of the contacts (6, 7) within the contactor 100.

After the contacts are closed—that is, the monostable period is over—the astable pulses continue to hold on the contacts (6, 7). The duty cycle at the rated voltage is determined based upon the spring force within the contactor 100. The duty cycle is designed for the minimum force required for holding the contacts on at a rated voltage, this aspect thus ensuring minimum coil energy consumption. As the coil assembly 3 supply voltage decreases, the resistance offered by voltage dependent resistor circuit 16 increases. The voltage dependent resistor circuit ensures that the pulse width of the astable pulse 23 increases with the decreasing supply voltage. This increases the duty cycle of the astable mode linearly with the decrease in voltage. This operation ensures the nearly constant hold on force within the assembly coil 3. Further, in the event that the coil voltage drops below the predetermined dropout voltage, the controller 18 resets the astable pulse generator 17 (step 430), and the contacts 6 drop out.

While the invention has been described with reference to exemplary embodiments, it will be understood by those skilled in the art that various changes may be made and equivalents may be substituted for elements thereof without departing from the scope of the invention. In addition, many modifications may be made to adapt a particular situation or material to the teachings of the invention without departing from the essential scope thereof. Therefore, it is intended that the invention not be limited to the particular embodiments disclosed for carrying out this invention, but that the invention will include all embodiments falling within the scope of the claims.

What is claimed is:

1. An electromagnetic contactor device, the electromagnetic contactor device comprising:
a control module, the control module comprising:
a power circuit, wherein the power circuit comprises a coil assembly, further, the power circuit is configured to receive an AC or DC supply voltage; and
an analog control circuit, the analog control circuit being in communication with the power circuit, wherein the control circuit is configured to monitor a coil voltage within the coil assembly.

2. The device of claim 1, where in response to the coil voltage being greater than a predetermined dropout voltage, at the control circuit, a RESET input for an astable pulse produced from the pulse generator is set to HIGH.

3. The device of claim 2, where in response to the coil voltage being greater than a determined pickup voltage, then at the control circuit, the RESET input of a monostable pulse produced from the pulse generator is set to HIGH.

4. The device of claim 3, wherein the pulse generator is configured to generate a monostable pulse output for a time period that is greater than or equal to a predetermined pickup time period for the device.

5. The device of claim 4, wherein the pulse generator is configured to combine the astable pulse and the monostable pulse in order to produce a resultant monostable pulse of a predetermined time period.

6. The device of claim 5, wherein the generation of the astable pulse continues after the time period for the generation of the monostable pulse has ceased.

7. The device of claim 6, where in response to the coil supply voltage decreasing the duty cycle of the astable pulse is linearly increased with the decrease in coil voltage.

8. The device of claim 7, wherein the astable pulse is reset in response to the coil voltage being less than the predetermined dropout voltage.

9. The device of claim 8, wherein the power circuit delivers a constant power supply to the analog control circuit.

10. The device of claim 9, wherein the constant power supply is delivered to the analog control circuit in response to a predetermined supply voltage that is delivered to the power circuit, the supply voltage being selected from a predetermined range of supply voltages.

11. The device of claim 10, wherein the power circuit further comprises a LDO voltage regulator and a switching voltage regulator, the LDO voltage regulator and the switching voltage regulator being utilized individually or in combination to deliver a constant power supply in response to a supply voltage that is selected from the predetermined range of supply voltages.

12. A method for utilizing a control module as an interfaced control of an AC/DC control coil, the method comprising:
monitoring a coil voltage of a control coil;
determining if the coil voltage is greater than a predetermined dropout voltage;
determining if the coil voltage is greater than a predetermined pickup voltage; and
resetting an astable pulse in response to the coil voltage being determined to be less than the predetermined dropout voltage.

13. The method of claim 12, where in response to the coil voltage being greater than a predetermined dropout voltage a RESET input for a generated astable pulse is set to HIGH.

14. The method of claim 13, where in response to the coil voltage being greater than a determined pickup voltage, then the RESET input of a generated monostable pulse is set to HIGH.

15. The method of claim 14, wherein a monostable pulse output is generated for a time period that is greater than or equal to a predetermined pickup time period.

16. The method of claim 15, wherein the astable pulse and the monostable pulse are combined in order to produce a resultant monostable pulse of a predetermined time period.

17. The method of claim 16, wherein the astable pulse continues to generate after the time period for the generation of the monostable pulse has ceased.

18. The method of claim 17, where in response to the coil supply voltage being determined to be decreasing, the duty cycle of the astable pulse is linearly increased with the decrease in coil voltage.
